(19) United States
(12) Patent Application Publication
(10) Pub. No.: US 2025/0194156 A1
(43) Pub. Date: Jun. 12, 2025

(54) DEEP SOURCE/DRAIN WITH SIDEWALL LINER PROTECTION AND DIRECT BACKSIDE CONTACT

(71) Applicant: International Business Machines Corporation, Armonk, NY (US)

(72) Inventors: Lijuan Zou, Albany, NY (US); Tao Li, Slingerlands, NY (US); Ruilong Xie, Niskayuna, NY (US); Eric Miller, Albany, NY (US)

(21) Appl. No.: 18/536,395

(22) Filed: Dec. 12, 2023

(51) Int. Cl. H01L 29/423; H01L 21/8238; H01L 23/528; H01L 27/092; H01L 29/06; H01L 29/08; H01L 29/66; H01L 29/775; H01L 29/786

(52) U.S. Cl. CPC H10D 30/6735; H01L 23/5286; H10D 30/014; H10D 30/43; H10D 30/6757; H10D 62/121; H10D 62/151; H10D 64/017; H10D 84/0167; H10D 84/017; H10D 84/0186; H10D 84/038; H10D 84/85

(57) ABSTRACT

A semiconductor device includes a first nanosheet stack on a front side of a semiconductor substrate, a second nanosheet stack on the front side of the semiconductor substrate separated from the first nanosheet stack by a source/drain region, and a deep nanosheet trench extends into the source/drain region between first and second nanosheet stacks. A source/drain is in the deep nanosheet trench and includes a bottom end having a backside source/drain divot formed therein. A deep trench liner is interposed between the deep nanosheet trench and the source/drain, the deep trench liner having an opening exposing the bottom end of the source/drain. A backside contact is on a backside of the semiconductor device, the backside contact physically contacting the exposed bottom end of the source/drain.

### BACKGROUND

The present disclosure generally relates to fabrication methods and resulting structures for semiconductor devices, and more specifically, to processing methods and resulting structures for providing a deep source/drain with sidewall liner protection and direct backside contact.

The development of an integrated circuit (i.e., chip) involves several stages from design through fabrication. Many aspects of the development are performed iteratively to ensure that the chip ultimately manufactured meets all design requirements. Defining the chip architecture is one of the earliest phases of integrated circuit development. The power (e.g., power requirement), performance (e.g., timing), and area (i.e., space needed) for the resulting chip, collectively referred to as “PPA”, is one of the primary metrics by which integrated circuits are evaluated. PPA is largely a consequence of the chip architecture.

Semiconductor fabrication continues to evolve towards improving one or more aspects of PPA. For example, a higher number of active devices (mainly transistors) of ever decreasing device dimensions are placed on a given surface of semiconductor material. Density scaling has put a strain on the design and fabrication of the interconnects between the front end of line of the integrated circuit, consisting mainly of the active devices, and the contact terminals of the integrated circuit. In many chip architectures, all of these interconnects are incorporated in the back end of line (BEOL) structure of the integrated circuit, which includes a stack of metallization layers and vertical via connections built on top of the front end of line (FEOL) structure.

A key component of the BEOL structure is the power delivery network (PDN). The PDN of an integrated circuit is defined by the conductors and vias connected to the power supply (VDD) and ground (VSS) terminals of the chip. The PDN is responsible for delivering power to the individual devices in the front end. The integration of the PDN in the BEOL has become particularly challenging as device densities continue to scale. Backside power delivery is one known solution to this problem, and involves moving some (or most, or all) layers of the PDN from the front side of the integrated circuit to the back side. In a backside-style architecture, the repositioned layers are not formed on top of the FEOL, but are instead formed on the opposite side of the chip (i.e., on the backside of the semiconductor substrate onto which the active devices have been built). One or more backside contacts are then formed on the backside to establish electrical connection with the PDN.

### SUMMARY

According to a non-limiting embodiment, a semiconductor device includes a first nanosheet stack on a front side of a semiconductor substrate, a second nanosheet stack on the front side of the semiconductor substrate separated from the first nanosheet stack by a source/drain region, and a deep nanosheet trench extends into the source/drain region between first and second nanosheet stacks. A source/drain is in the deep nanosheet trench and includes a bottom end having a backside source/drain divot formed therein. A deep trench liner is interposed between the deep nanosheet trench and the source/drain, the deep trench liner having an opening exposing the bottom end of the source/drain. A backside contact is on a backside of the semiconductor device, the backside contact physically contacting the exposed bottom end of the source/drain.

According to another non-limiting embodiment, A semiconductor device comprises a first nanosheet stack on an upper surface of a front side of a semiconductor substrate, a second nanosheet stack on the upper surface, and a third nanosheet stack on the upper surface. A first deep source/drain is interposed between the first nanosheet stack the second nanosheet stack, and a second deep source/drain is interposed between the second nanosheet stack the third nanosheet stack. A backside contact is on a backside of the semiconductor substrate and is in physical contact with a first bottom end of the first deep source/drain. A source/drain seed layer is in physical contact with a second bottom end of the second deep source/drain.

According to yet another non-limiting embodiment a method of fabricating a semiconductor device comprises forming a deep nanosheet trench between first and second nanosheet stacks formed on a frontside of semiconductor substrate, and depositing a deep trench liner on sidewalls and a bottom end of the deep nanosheet trench. The method further comprises forming a source/drain in the deep nanosheet trench, and etching a backside of the semiconductor substrate to form a backside contact trench which exposes the deep nanosheet trench while the deep trench liner prevents etching of the source/drain. The method further comprises etching the bottom end of the deep nanosheet trench to expose a bottom end of the source/drain, and forming a backside contact in the backside contact trench to establish physical contact between the backside contact and the bottom end of the source/drain.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1A depicts a top-down view of a semiconductor wafer after an initial set of processing operations according to one or more embodiments;

FIG. 1B depicts a cross-sectional view taken along the line X (across gate in channel region) in FIG. 1A after the initial set of processing operations according to one or more embodiments;

FIG. 1C depicts a cross-sectional view taken along the line Y (across channel in source/drain region) in FIG. 1A after the initial set of processing operations according to one or more embodiments;

FIG. 2A depicts a cross-sectional view taken along the line X after a processing operation according to one or more embodiments;

FIG. 2B depicts a cross-sectional view taken along the line Y after the processing operation according to one or more embodiments;

FIG. 3A depicts a cross-sectional view taken along the line X after a processing operation according to one or more embodiments;

FIG. 3B depicts a cross-sectional view taken along the line Y after the processing operation according to one or more embodiments;

FIG. 4A depicts a cross-sectional view taken along the line X after a processing operation according to one or more embodiments;

FIG. 4B depicts a cross-sectional view taken along the line Y after the processing operation according to one or more embodiments;

FIG. 5A depicts a cross-sectional view taken along the line X after a processing operation according to one or more embodiments;

FIG. 5B depicts a cross-sectional view taken along the line Y after the processing operation according to one or more embodiments;

FIG. 6A depicts a cross-sectional view taken along the line X after a processing operation according to one or more embodiments;

FIG. 6B depicts a cross-sectional view taken along the line Y after the processing operation according to one or more embodiments;

FIG. 7A depicts a cross-sectional view taken along the line X after a processing operation according to one or more embodiments;

FIG. 7B depicts a cross-sectional view taken along the line Y after the processing operation according to one or more embodiments;

FIG. 8A depicts a cross-sectional view taken along the line X after a processing operation according to one or more embodiments;

FIG. 8B depicts a cross-sectional view taken along the line Y after the processing operation according to one or more embodiments;

FIG. 9A depicts a cross-sectional view taken along the line X after a processing operation according to one or more embodiments;

FIG. 9B depicts a cross-sectional view taken along the line Y after the processing operation according to one or more embodiments;

FIG. 10A depicts a cross-sectional view taken along the line X after a processing operation according to one or more embodiments;

FIG. 10B depicts a cross-sectional view taken along the line Y after the processing operation according to one or more embodiments;

FIG. 11A depicts a cross-sectional view taken along the line X after a processing operation according to one or more embodiments;

FIG. 11B depicts a cross-sectional view taken along the line Y after the processing operation according to one or more embodiments;

FIG. 12A depicts a cross-sectional view taken along the line X after a processing operation according to one or more embodiments;

FIG. 12B depicts a cross-sectional view taken along the line Y after the processing operation according to one or more embodiments;

FIG. 13A depicts a cross-sectional view taken along the line X after a processing operation according to one or more embodiments;

FIG. 13B depicts a cross-sectional view taken along the line Y after the processing operation according to one or more embodiments;

FIG. 14A depicts a cross-sectional view taken along the line X after a processing operation according to one or more embodiments;

FIG. 14B depicts a cross-sectional view taken along the line Y after the processing operation according to one or more embodiments;

FIG. 15A depicts a cross-sectional view taken along the line X after a processing operation according to one or more embodiments;

FIG. 15B depicts a cross-sectional view taken along the line Y after the processing operation according to one or more embodiments;

FIG. 16A depicts a cross-sectional view taken along the line X after a processing operation according to one or more embodiments;

FIG. 16B depicts a cross-sectional view taken along the line Y after the processing operation according to one or more embodiments; and

FIG. 17 depicts a cross-sectional view taken along the line X after the processing operation of FIG. 16A according to one or more embodiments.

The diagrams depicted herein are illustrative. There can be many variations to the diagram or the operations described therein without departing from the spirit of the disclosure. For instance, the actions can be performed in a differing order or actions can be added, deleted or modified.

In the accompanying figures and following detailed description of the described embodiments of the disclosure, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the disclosure are described in connection with a particular transistor architecture, embodiments of the disclosure are not limited to the particular transistor architectures or materials described in this specification. Rather, embodiments of the present disclosure are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present disclosure, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

As discussed previously, a key component of the BEOL structure is the power delivery network (PDN). Backside power delivery, also referred to as a backside power delivery network (BSPDN), is a chip architecture that involves repositioning layers of the PDN from the top of the FEOL to the opposite side of the chip to free space on the front side for additional elements (e.g., more transistors). In other words, in a backside-style architecture the PDN layers are placed on the backside of the semiconductor substrate onto which the active devices have been built.

Some challenges remain, however, in effectively placing the various backside power rails and backside contacts in relation to the gate contact. In particular, it becomes more difficult to avoid shorting between the backside contact and the gate contact (typically referred to as “backside contact-to-gate shorting”) as semiconductor footprints continue to decrease.

This disclosure introduces new fabrication methods and resulting structures for providing a semiconductor device including a deep source/drain with sidewall liner protection and direct backside contact. The result is a greatly increased interface between the backside source/drain contact and the source/drain epitaxy. Increasing the available interface between the backside source/drain contact and the source/drain epitaxy enables better device performance. Formation of the deep source/drains also omit the need utilize placeholders for Direct Backside Contact (DBC) flow since the deep source/drains require shallower backside contact patterning. As a result, the patterning and material used to form the placeholders can be omitted while still preventing backside contact-to-gate shorting.

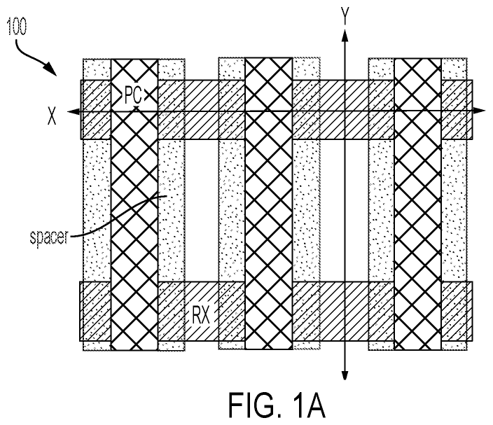

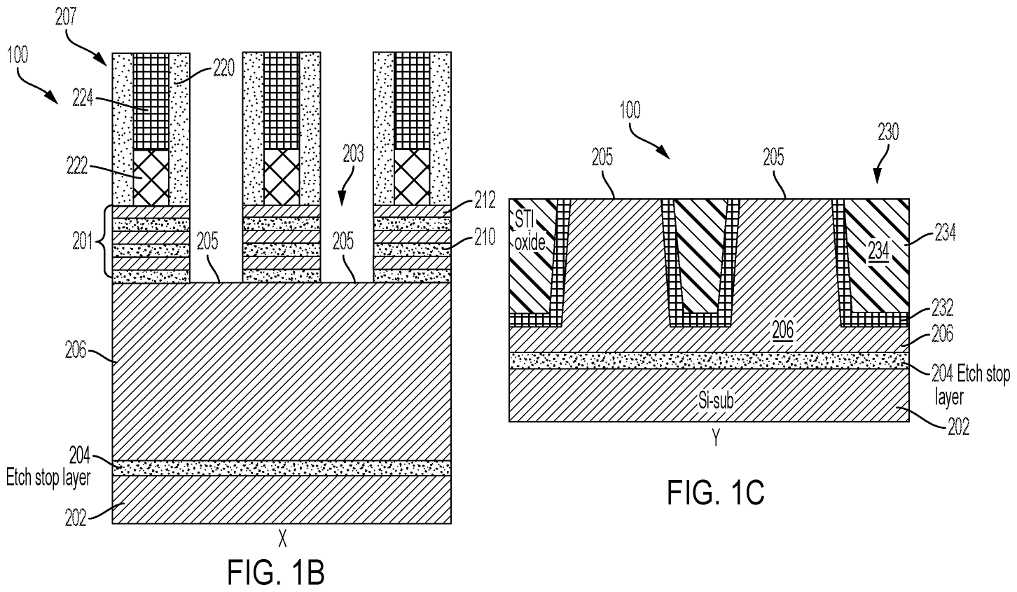

Turning now to a more detailed description of fabrication operations and resulting structures according to aspects of the disclosure, FIG. 1A depicts a top-down reference view of a semiconductor device 100 after an initial set of fabrication operations (e.g., through FEOL) have been applied as part of a method of fabricating a final semiconductor device according to one or more embodiments of the disclosure. FIG. 1B depicts a cross-sectional view taken along the line X (across gate in channel region) in FIG. 1A. FIG. 1C depicts a cross-sectional view taken along the line Y (across channel in source/drain region) in FIG. 1A.

As shown in FIGS. 1A-1C, various FEOL structures have been built in the semiconductor wafer 100. The specific examples of the FEOL structures are illustrative only and are not meant to be particularly limited. For example, the FEOL structures depict a nanosheet-style transistor architecture. It should be understood, however, that the nanosheet-style transistor architecture of the FEOL structures is provided for ease of discussion only and that other transistor architectures (e.g., vertical tunneling transistors, planar transistors, finFETs, etc.) are included in the contemplated scope of this disclosure. Other FEOL structures can be fabricated depending on the needs of a given application, and all such configurations are within the contemplated scope of this disclosure.

In FIG. 1B, the semiconductor device 100 is shown including a first sacrificial layer 204 deposited on top of a substrate 202, and a semiconductor layer 206 formed on the first sacrificial layer 204. The first sacrificial layer 204 may be, for example, a sacrificial low-Ge % SiGe such as, for example, SiGe30%. The first sacrificial layer 204 will act as an etch stop when removing the substrate 202 in subsequent fabrication operations. A semiconductor layer 206 can be formed by epitaxially growing a semiconductor layer such as a of silicon (Si), for example, from an upper surface of the first sacrificial layer 204.

With continued reference to FIGS. 1B, the semiconductor device 100 is illustrated after the formation of nanosheet stacks 201 and gate stacks 207. The nanosheet stacks 201 are formed on the semiconductor layer 206 (e.g., a frontside of the substrate 202) and separated from one another by voids 203 that expose portions 205 of the semiconductor layer 206. Each of the exposed portions 205 define source/drain regions of the semiconductor layer 206, which are regions designated to form source/drains at later stages of the process flow described herein.

Each nanosheet stack 201 includes alternating arrangement of sacrificial layers 210 and channel layers 212 stacked on top of one another. The sacrificial layers 210 can be a sacrificial low-Ge % SiGe such as, for example, SiGe30%. The channel layers 212 can be Si, for example, and will serve as the nanosheet layers that form the semiconductor channel(s) of the semiconductor device 100.

The gate stacks 207 are formed over the channel regions of the nanosheet stacks 201, respectively. As used herein, a “channel region” refers to the portion of that nanosheet stack 201 over which the gate stack 207 is formed, and through which current passes from source to drain in the final device. Each gate stack 207 includes an opposing pair of gate spacers 220, a sacrificial gate 222 (sometimes referred to as a “dummy gate”) formed between the spacers 220 and on the semiconductor layer 206, and a gate cap 224 formed between the spacers 220 and on the sacrificial gate 222.

In FIG. 1C, the initial set of fabrication operations applied to the semiconductor device 100 also form shallow trench isolation (STI) regions 230 in the semiconductor layer 206. The formation of the STI regions 230 includes forming STI trenches in the semiconductor layer 206, depositing a conformal STI liner 232 on the bottom surface and sidewalls of the STI trench, and then filling the STI trench with an insulation material 234. The STI liner 232 is formed from an insulative material such as silicon nitride (SiN), for example, and can be deposited using various depositing process such as, for example, low pressure chemical vapor deposition (LPCVD) or plasma enhanced chemical vapor deposition (PECVD), and has a thickness ranging, for example, from about 3 nm to about 12 nm. The insulation material used to fill the STI trenches can include, for example, silicon oxide (SiO2). In one or more non-limiting embodiments, the STI trenches can be overfilled with the insulation material 234, and a chemical mechanical planarization (CMP) process can be performed to planarize the upper surface of the STI regions 230.

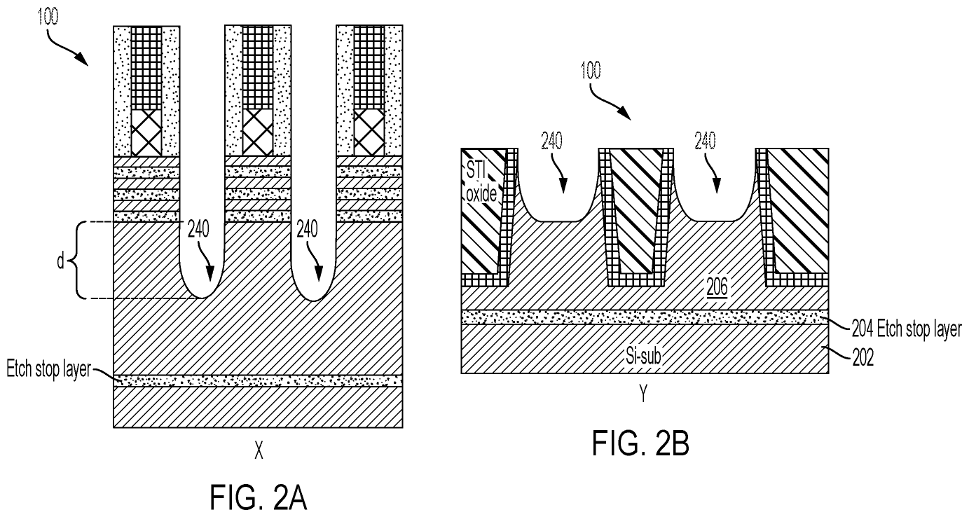

Turning now to FIGS. 2A and 2B, the semiconductor device 100 is illustrated after forming deep nanosheet trenches 240 in the semiconductor layer 206. The deep nanosheet trenches 240 can be formed by performing recessing the portions of the exposed semiconductor layer exposed by the voids 203. In one or more non-limiting embodiments, a reactive ion etch (RIE) process is performed to recess the exposed portions of the semiconductor layer 206 below the nanosheet stack 201 as shown in FIG. 2A. The deep nanosheet trenches 240 can extend into the semiconductor layer 206 at a depth (d) reaching the backside of the semiconductor substrate ranging, for example, from about 20 nm to about 90 nm.

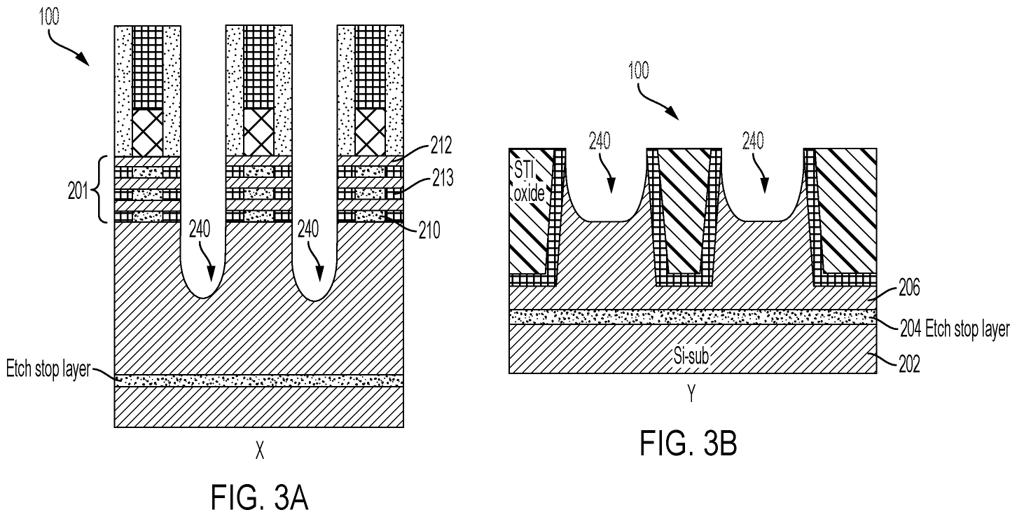

In FIGS. 3A and 3B, the semiconductor device 100 is illustrated after forming inner spacers 213 on the ends of the sacrificial layers 210. The inner spacers 213 can be formed by performing an etching process the is selective to the material of the sacrificial layers 210 (e.g., SiGe) that recesses the ends of the sacrificial layers 210 and forms cavities (not shown). A conformal spacer layer (not shown) is formed of SiO2, SiOCN, SiOC, SiBCN, for example, can then be deposited on the semiconductor device 100, which fills the cavities, and a directional RIE process is performed that removes the spacer liner from the sidewalls of the nanosheet stacks 201. The portion of the spacer layer that remains filling the cavities defines the inner spacers.

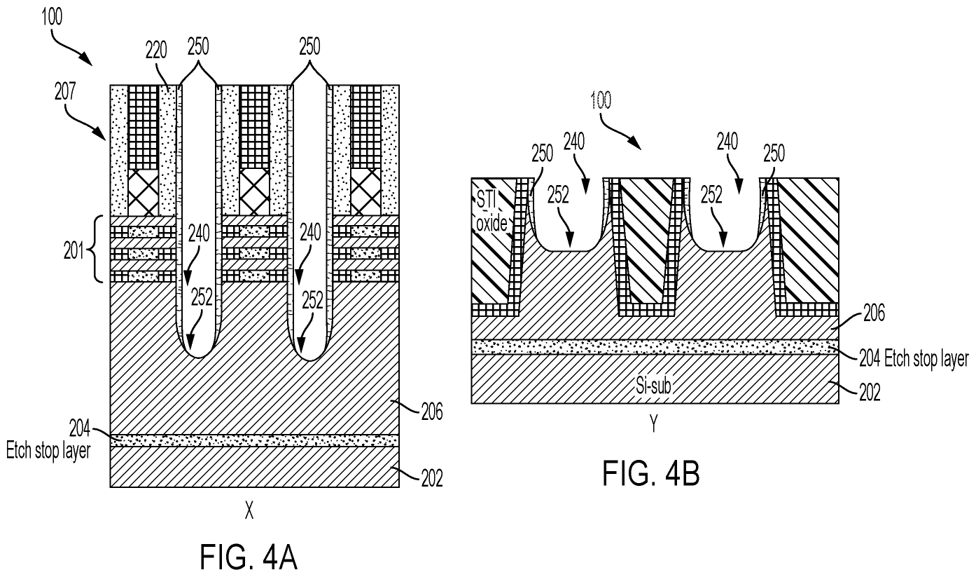

FIGS. 4A and 4B, the semiconductor device 100 is illustrated after depositing a deep trench liner 250. According to a non-limiting embodiment, the deep trench liner 250 can be formed by conformally depositing a material against the gate stacks 207, the nanosheet stacks 201, and the nanosheet deep trenches 240. A directional etch such as an RIE process, for example, can then be performed to form an opening 252 in the deep trench liner 250 to expose an underlying portion of the semiconductor layer 206.

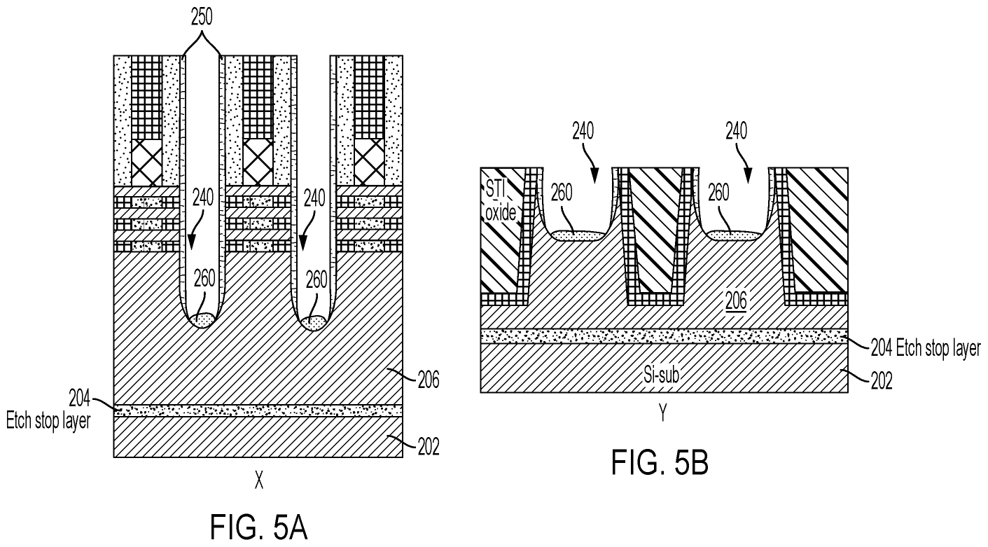

Turning to FIGS. 5A and 5B, the semiconductor device 100 is illustrated after forming source/drain (S/D) seed layers 260, which will be used to form the S/Ds (not shown in FIGS. 5A and 5B) of the semiconductor device 100. The S/D seed layers 260 can be formed by epitaxially growing a semiconductor material from the semiconductor layer 206 exposed by the deep trench liner opening 252. According to a non-limiting embodiment, the S/D seed layers 260 are formed from SiGe; however, it should be appreciated that other semiconductor materials can be used to form the S/D seed layers 260 without departing from the scope of the present disclosure, provided that S/D seed layer 260 is different semiconductor layer than substrate 206.

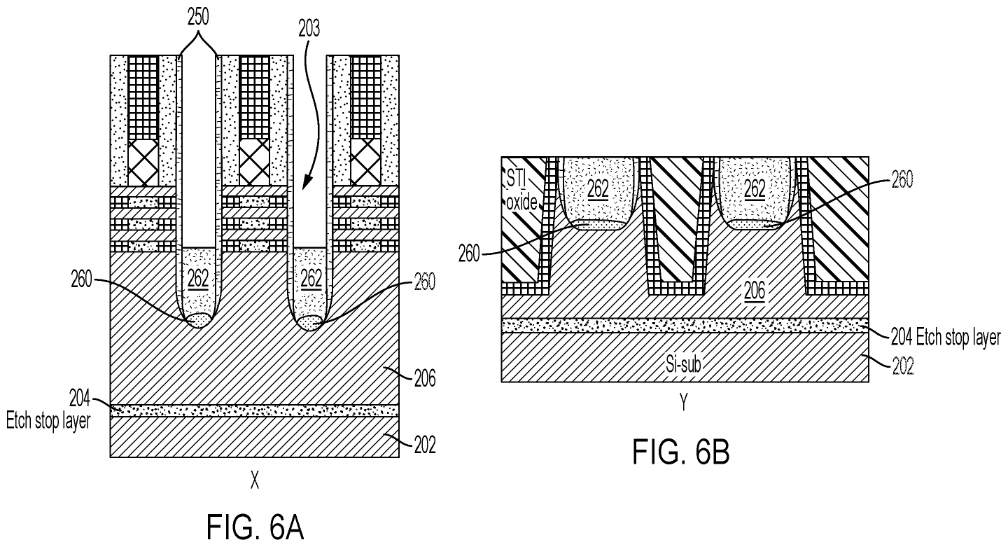

In FIGS. 6A and 6B, the semiconductor device 100 is shown after covering the S/D seed layers 260 with an organic planarization layer (OPL) 262. The OPL 262 can be formed by overfilling the voids 203 with an OPL material, and the partially recessing the OPL material using a RIE process, for example, which stops on an upper surface of the semiconductor layer 206. The OPL material can include, but is not limited to, polyimides, benzocyclobutene (BCB), and spin-on glass, and can be deposited using chemical vapor deposition (CVD), physical vapor deposition (PVD) and spin-coating.

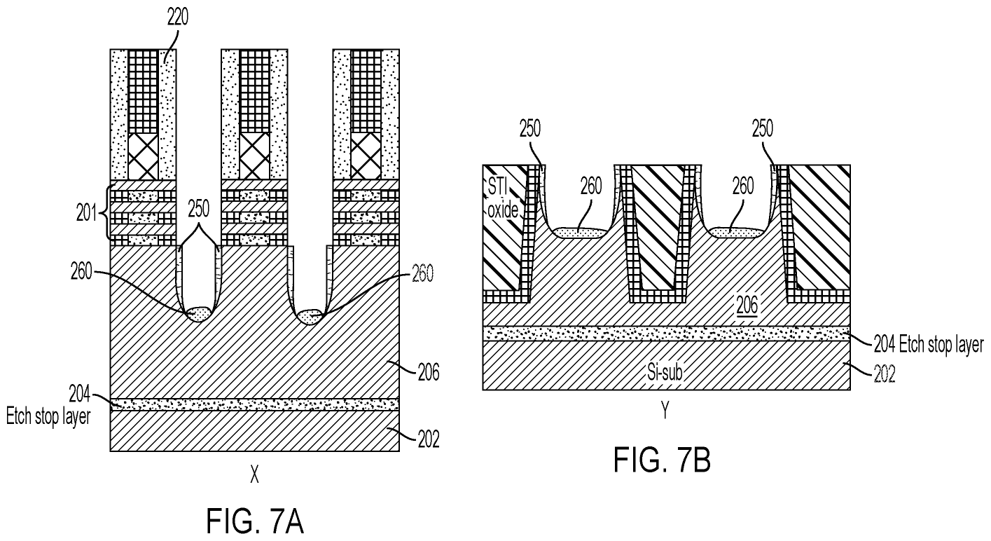

In FIGS. 7A and 7B, the semiconductor device 100 is shown following partial recess of the deep trench liner 250 and removal of the OPL 262. According to a non-limiting embodiment, the deep trench liner 250 can be etched using an RIE etch, which stops on an upper surface of the OPL 262. Accordingly, the deep trench liner 250 is removed from the gate spacers 220 and the nanosheet stack 201. An OPL ashing technique can then be performed to remove the OPL 262. According to a non-limiting embodiment, the OPL ashing technique uses an oxygen plasma chemistry, for example, which selectively removes the OPL material without etching, or substantially attacking, the underlying dielectric deep trench liner 250 and the S/D seed layers 260. That is, the material of the OPL is reactive to the chemistry of the oxygen plasma chemistry (e.g., is selective to the oxygen plasma chemistry) while the dielectric material of the trench liner 250 and the SiGe of the seed layers 260 are not reactive to the chemistry of the oxygen plasma chemistry (e.g., are non-selective to the oxygen plasma chemistry). Accordingly, the deep nanosheet trenches 240 are reopened in the semiconductor layer 206 to expose the S/D seed layers 260.

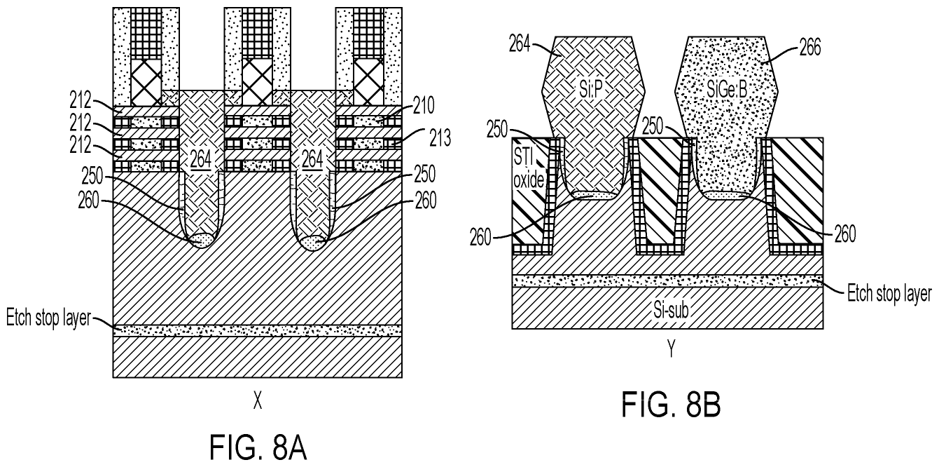

In FIGS. 8A and 8B, the semiconductor device 100 is shown after forming deep source/drains (S/Ds) 264 and 266 in the deep nanosheet trenches 240. According to a non-limiting embodiment, the deep source/drains (S/Ds) 264 and 266 are formed by epitaxially growing a semiconductor material from the S/D seed layers 260 and the ends of the channel layers 212. When fabricating a CMOS semiconductor device, for example, phosphorus-doped silicon (Si:P) can be grown to form an n-type S/D 264 corresponding to the n-type field effect transistor (nFET), and boron-doped silicon germanium (SiGe:B) can be grown to form a p-type S/D 266 corresponding to the p-type field effect transistor (pFET). It should be appreciated, however, that other dopants can also be used for the n-type or the p-type source/drain without departing from the scope of the present disclosure.

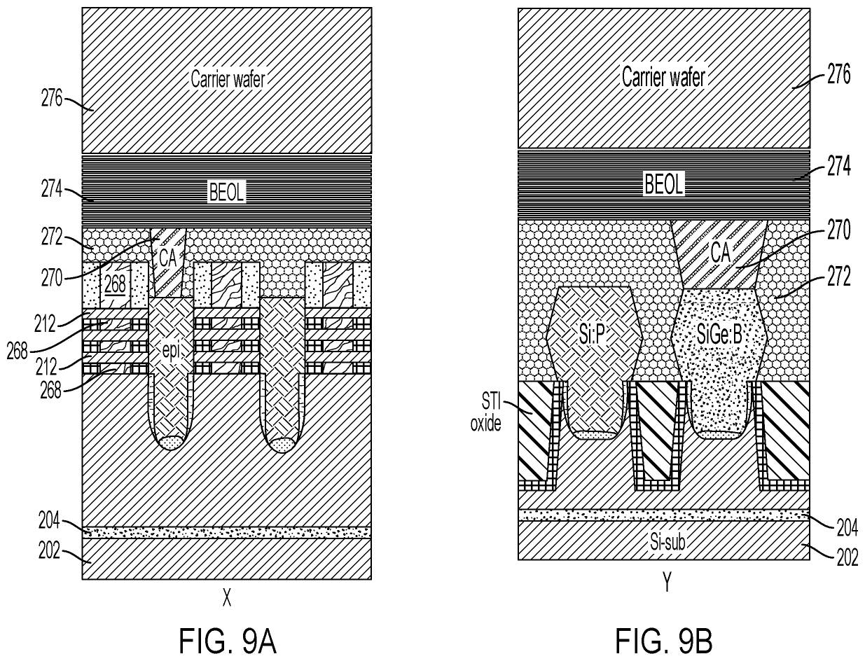

Turning now to FIGS. 9A and 9B, the semiconductor device 100 is illustrated after replacing the sacrificial gate 222 with an electrically conductive gate 268 (also referred to as a gate electrode). To remove the sacrificial gate 222 and the sacrificial layers 210 before depositing the gate electrode material, a non-limiting embodiment performs a combination of a partial dry etch and partial wet etch, which forms a gate trench (not shown) that will support the gate electrode 268. In other embodiments of the present disclosure, the sacrificial gate 222 and the sacrificial layers 210 can be removed using a full dry etch scheme.

Formation of the gate electrode 268 includes depositing a HKMG material in the gate trench to form a high-k metal gate (HKMG) 268, which wraps all around the nanosheet stack 201 (e.g., the channel layers 212). The HKMG 268 includes depositing a high-k dielectric such as HfO2, ZrO, HfLaOx, HfAlOx, etc., and workfunction metal (WFM) such as TIN, TiC, TiAlC, TiAl, etc. The HKMG 268 may further comprise optional low resistance conducting metals such as W, Co and Ru.

The work function metal (not shown) can comprise a metal selected so as to have a specific work function appropriate for a given type FET (e.g., an N-type FET or a P-type FET). For example, for a silicon-based N-type FET, the work function metal can comprise hafnium, zirconium, titanium, tantalum, aluminum, or alloys thereof, such as hafnium carbide, zirconium carbide, titanium carbide, tantalum carbide, or aluminum carbide, so that the work function metal has a work function similar to that of N-doped polysilicon. For a silicon-based P-type FET, the work function metal can comprise, for example, ruthenium, palladium, platinum, cobalt, or nickel, or a metal oxide (e.g., aluminum carbon oxide or aluminum titanium carbon oxide) or a metal nitride (e.g., titanium nitride, titanium silicon nitride, tantalum silicon nitride, titanium aluminum nitride, or tantalum aluminum nitride) so that the work function metal has a work function similar to that of P-doped polysilicon.

With continued reference to FIGS. 9A and 9B, one or more middle-of-line (MOL) structures 270, an interlayer dielectric 272, and one or more back-end-of-line (BEOL) structures 274 are formed on the semiconductor device 100. The MOL structures 270 include one or more contacts 270 formed on the S/Ds 264 and 266, following by deposition of the ILD layer 272 on top of the semiconductor device 100. The epitaxy contacts 270 may be made out of any suitable material including, for example, a silicide liner at bottom of the contact such as Ti, Ni, NiTi, NiPt, and a conductive metal such as Ru or W, or Co, with a thin adhesion metal liner such as TiN. The BEOL structure 274 can include a number of interconnects or other structures. Following formation of the MOL structures 270 and BEOL structures 274, the semiconductor device 100 is bonded to a carrier wafer 276.

It should be appreciated that the dimensions of the MOL structures 270 (e.g., the contacts) 244, ILD 272, BEOL structures 274, and carrier wafer 276, are not necessarily drawn to scale. In addition, MOL structures 270 (e.g., the contacts) 244, ILD 272, BEOL structures 274, and carrier wafer 276 can be formed using any suitable processes, as would be recognized by a person of ordinary skill in the art. In some embodiments, BEOL structures 274, and carrier wafer 276 can be pre-fabricated and then bonded with the semiconductor device 100.

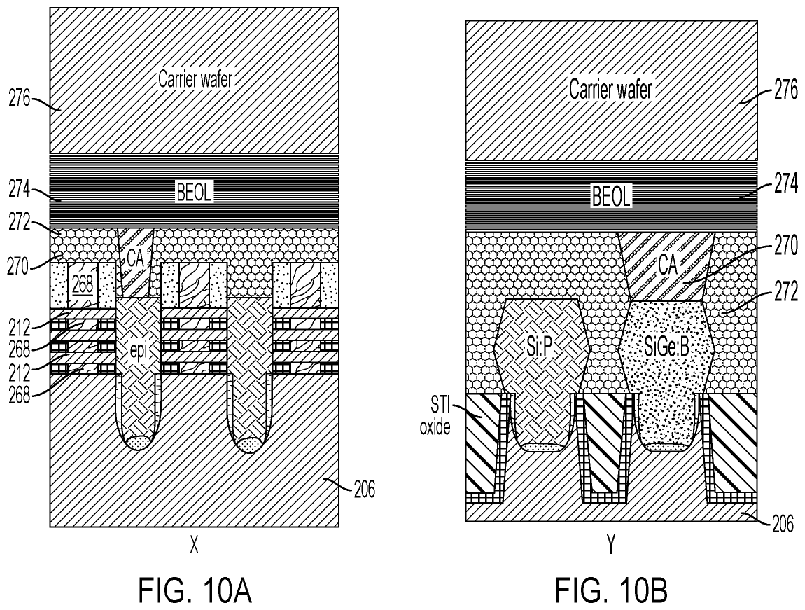

Turning now to FIGS. 10A and 10B, the substrate 202 is removed from the semiconductor device 100. When removing the substrate 202, an etching chemistry can be used that is selective to the material of the substrate. Accordingly, the first sacrificial layer 204, can serve as an etch stop. Accordingly, the substrate 202 can be removed through a selective etching process that stops on the first sacrificial layer 204. The first sacrificial layer 204 can then be etched and removed. Although not illustrated, the semiconductor device 100 can be flipped at this stage so that the substrate 202 and first sacrificial layers 204 can be removed, along with performing additional backside fabrication processes.

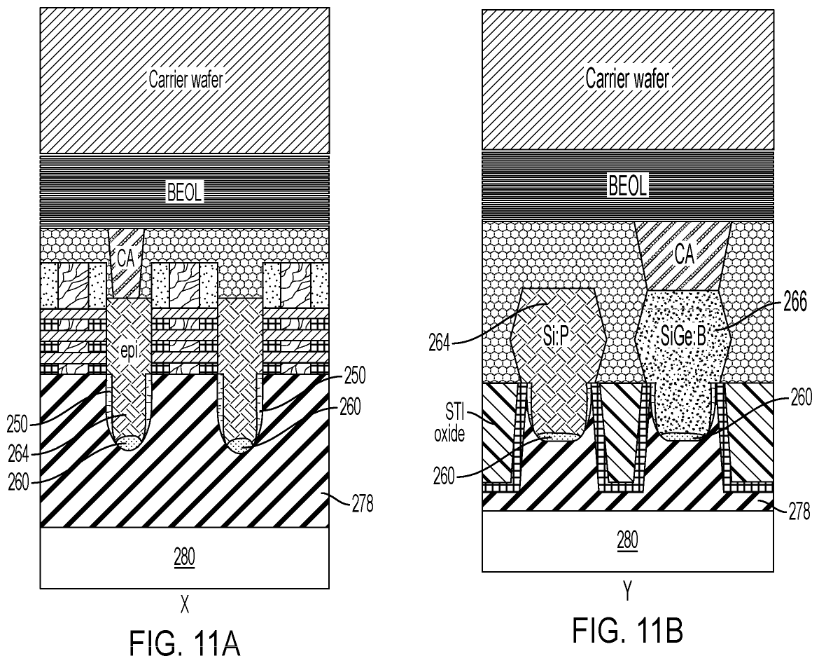

In FIGS. 11A and 11B, the semiconductor device 100 is illustrated after replacing the semiconductor layer 206 with a backside ILD 278. The backside ILD 278 can include various oxide or insulating materials and can be deposited using, for example, a plasma-enhanced chemical vapor deposition (PECVD) process. In one or more non-limiting embodiments, the etching process used to remove semiconductor layer 206 is selective to the Si, which is also found in the nFET S/Ds 264. However, the dielectric deep trench liners 250 and the S/D seed layers 260 (e.g. SiGe) prevent the etching process from damaging the nFET S/Ds 264.

After depositing the ILD 278, a backside organic OPL 280 can be formed on the backside ILD 278. The backside OPL 280 can be formed using spin-on coating or other suitable processing such as spin-on processes, although low temperature CVD amorphous carbon (a-C) could also be used. The backside OPL 280 may be formed of or using a precursor such as polyacrylate resin, epoxy resin, phenol resin, polyamide resin, polyimide resin, unsaturated polyester resin, polyphenylenether resin, polyphenylenesulfide resin, benzocyclobutene (BCB), etc. More generally, the backside OPL 280 may be formed of a-C with a certain amount of non-metallic, non-Si elements. The backside OPL 280 may have a height or vertical thickness in the range of about 30 to 200 nm.

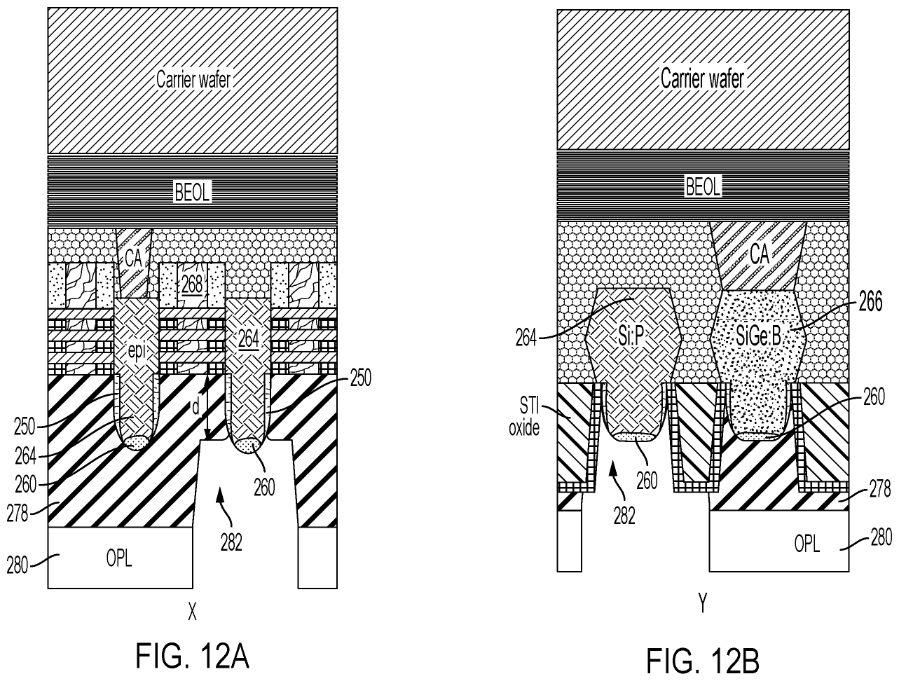

In FIGS. 12A and 12B, the backside ILD 278 and backside OPL 280 are patterned form a backside contact trench 282, which exposes a lower portion of a nFET S/D 264 designed to contact a backside S/D contact (not shown in FIGS. 12A and 12B). In one or more non-limiting embodiments, a RIE can be used, which has an etching chemistry that is selective to the material backside OPL 280 and backside ILD 278. That is, the materials of the backside OPL 280 and the backside ILD 278 are reactive (i.e., selective) to the chemistry of the RIE, while the dielectric material of the trench liner 250 and the SiGe of the seed layers 260 are not reactive (i.e., non-selective) to the etching chemistry of the RIE. Accordingly, the RIE form the backside contact trench 282 into the ILD 248, while the dielectric deep trench liners 250 and the S/D seed layer 260 prevent the etching process from damaging the nFET S/D 264. In one or more non-limiting embodiments, the etching process can be stopped once the S/D seed layer 260 is exposed. As a result, the distance (d) separating the gate electrode 268 and the contact trench 282 can range, for example, from about 20 nm to about 90 nm. In this manner, the distance between the gate electrode 268 and the backside contact trench 282 can be extended compared to the distance that results using conventional backside contact patterning processes.

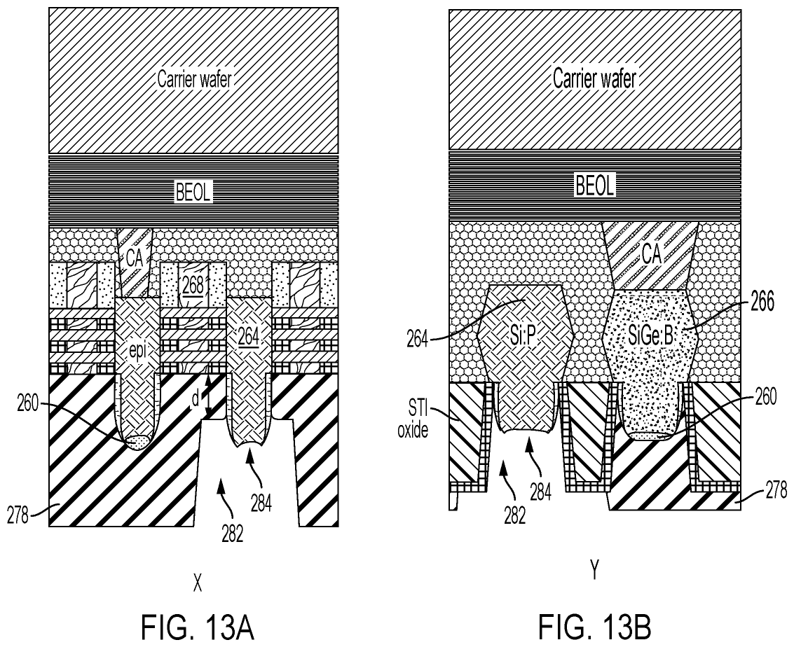

Turning to FIGS. 13A and 13B, the semiconductor device 100 is shown after removing the S/D seed layers 260. In one or more non-limiting embodiments, a timed RIE selective to SiGe is performed. As a result, a backside S/D divot 284 is formed which exposes the bottom portion of the nFET S/D 264.

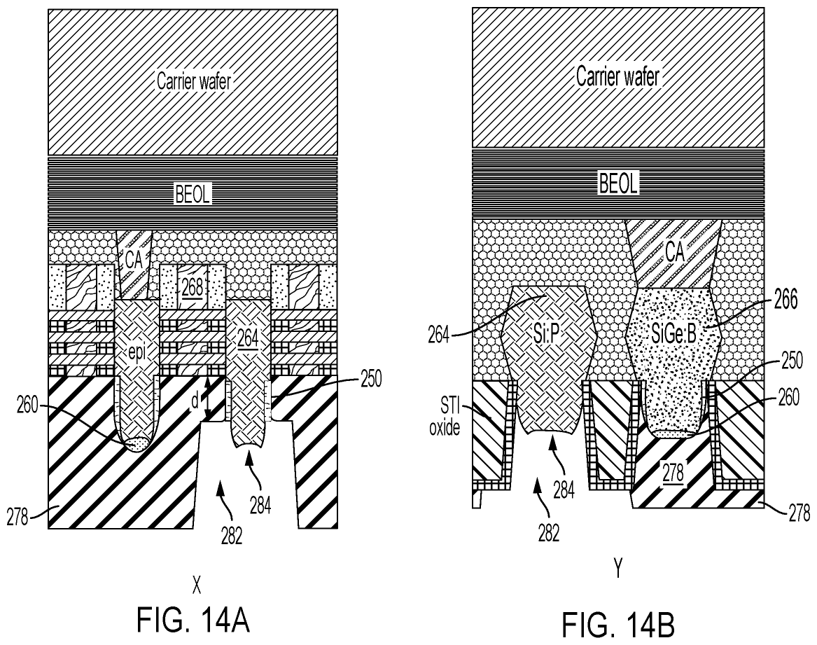

In FIGS. 14A and 14B, the exposed portions of the dielectric deep trench liners 250 are removed. Accordingly, the bottom sidewalls of the nFET S/D 264 are exposed, which provide additional surface area to establish contact between the nFET S/D 264 and a backside S/D contact (not shown in FIGS. 14A and 14B).

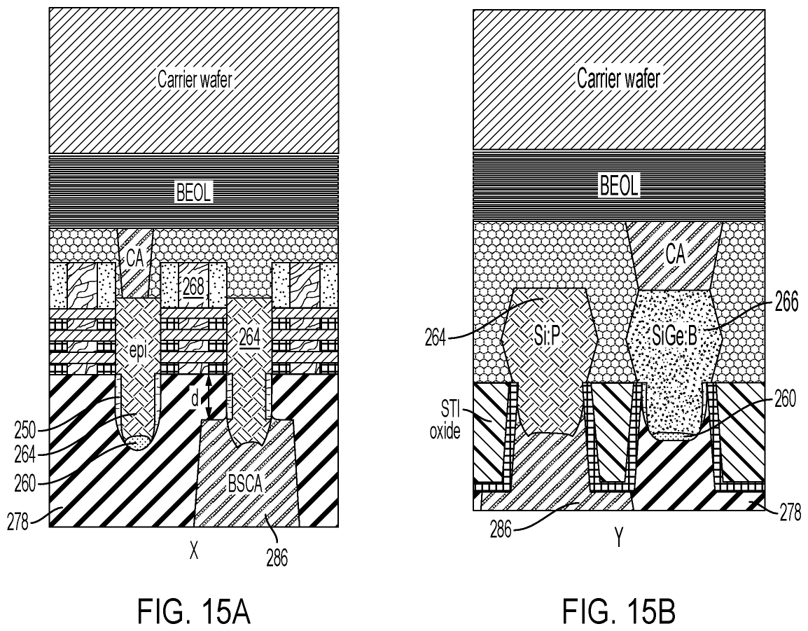

In FIGS. 15A and 15B, the semiconductor device 100 is illustrated after forming a backside contact 286 in the backside contact trench 282. The backside contact 286 (also referred to as a direct backside contact (DBC)) can be formed of any suitable conductive material such as copper (Cu), silver (Ag), or gold (Au). In some embodiments, the backside contact 286 can be formed as a silicide liner at the bottom of the contact such as Ti, Ni, NiTi, NiPt, and a conductive metal such as Ru or W, or Co, with a thin adhesion metal liner such as TiN. In at least one non-limiting embodiment of the present disclosure, the backside contact trench 282 can be overfilled with the conductive material, and a CMP process can be performed. Accordingly, one end of the backside contact 286 encapsulates the bottom end of the nFET S/D 264 and fills the backside S/D divot 284, while the opposing end of the backside contact 286 is co-planar (e.g., flush) with the surface of the backside ILD 278.

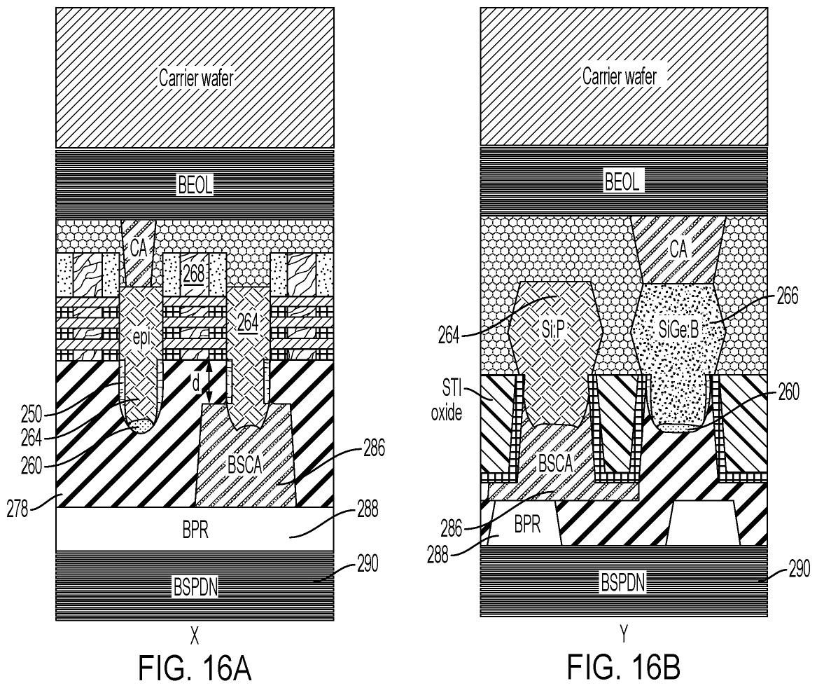

Turning now to FIGS. 16A and 16B, the semiconductor device 100 is illustrated after formation of one or more electrically conductive backside power delivery elements. The backside power delivery elements include, but are not limited to, one or more backside power rails (BPRs) 288 and a backside power distribution network (BSPDN) 290. The BSPDN 290 can include a network of low-resistive metal wires, which provides power supply and reference voltage (i.e., VDD and VSS) to the semiconductor device 100. Accordingly, one or more BPRs 288 can establish an electrically conductive path between the BSPDN 290 and the backside contact 286.

In one or more non-limiting embodiments of the present disclosure, the BPR 288 can be directly formed at least partially on a surface of the backside contact 286, and the BSPDN 290 is then formed on the BPR(s) 288.

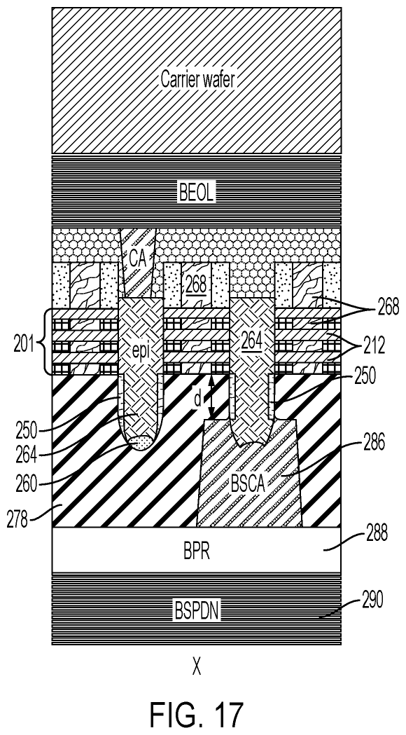

As shown in FIG. 17, the deep trench liners 250 protect the nFET S/D 264 while performing fabrications operations to form a backside contact 286 that establishes contact with the bottom portion of the nFET S/D 264. In one or more non-limiting embodiments, the deep trench liners 250 contact sidewalls of the source/drain 264, and extend from source/drain region (e.g., see source/drain regions 205 in FIG. 1B) to the end of the backside contact 286 that contacts the source/drain 264 does not. In at least one non-limiting embodiment, the backside contact (e.g., the end of backside contact 208 that contacts the source/drain 264) does not extend past the deep trench liners 250 (e.g., is below the deep trench liners 250). As a result, the backside contact 286 can be separated from the gate electrode 268 at a distance (e.g., about 20 nm to about 90 nm) that avoids backside contact-to-gate shorting.

In addition, the distance capable of avoiding the backside contact-to-gate shorting is achieved without relying on the need to form a backside contact placeholder, which is found in conventional fabrication operations. In this manner, the backside contact-to-gate shorting can be achieved using less materials and fabrication operations.

Also shown in FIG. 17, a first deep S/D 264 contacting a backside contact 286 excludes the S/D seed layer 260, while a second deep S/D 264 not contacting a backside contact (e.g., separated from backside contact 286) maintains the S/D seed layer 260 on the S/D bottom end. While the maintained S/D seed layer 260 does not impact device performance it can serve as a sort of a physical signature of the process for providing a semiconductor device that includes a deep source/drain with sidewall liner protection and direct backside contact as described herein.

As a further signature, the deep trench liners 250 formed on the deep S/D 264 contacting the S/D seed layer 260 have a greater length than the deep trench liners 250 formed on the deep S/D 264 contacting the backside contact 286. This physical feature is further indicative of the fabrication process used to provide a semiconductor device that includes a deep source/drain with sidewall liner protection and direct backside contact as described herein.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop (i.e., the second element remains). For example, material of a first element that is selective to an etching chemistry is reactive to the etching chemistry and is etched while material of a second element that is non-selective to the etching chemistry is not reactive to the etchant chemistry and is not etched.

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the disclosure of the disclosure, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of fabricating a semiconductor device, the method comprising:
forming a deep nanosheet trench between first and second nanosheet stacks formed on a frontside of semiconductor substrate;
depositing a deep trench liner on sidewalls and a bottom end of the deep nanosheet trench;
forming a source/drain in the deep nanosheet trench;
etching a backside of the semiconductor substrate to form a backside contact trench which exposes the deep nanosheet trench while the deep trench liner prevents etching of the source/drain;
etching the bottom end of the deep nanosheet trench to expose a bottom end of the source/drain;
and forming a backside contact in the backside contact trench to establish physical contact between the backside contact and the bottom end of the source/drain.

2. The method of claim 1, wherein forming the source/drain comprises:
etching the deep trench liner located at the bottom end of the deep nanosheet trench to form an opening which exposes a portion of semiconductor substrate;
forming a source/drain seed layer on the exposed portion of the semiconductor substrate; and
epitaxially growing the source/drain from the source/drain seed layer.

3. The method of claim 2, wherein etching a backside of the semiconductor substrate comprises:
replacing a portion of semiconductor material with a backside interlayer dielectric (ILD);
performing an etching process that is selective to material of the ILD and the source/drain while the deep trench liner prevents etching of sidewalls of the source/drain and the source/drain seed layer prevents etching of the bottom end of the source/drain.

4. The method of claim 3, wherein etching the bottom end of the deep nanosheet trench comprises performing an etching process that is selective to material of the source/drain seed layer to remove the source/drain seed layer and expose the bottom end of the source/drain.

5. The method of claim 4, wherein forming the backside contact comprises:
performing an etching process that is selective to material of the deep trench liner to remove the deep trench liner from the sidewalls of the source/drain; and
filling the backside contact trench with an electrically conductive metal so to encapsulate the sidewalls and the bottom end of the source/drain.

6. The method of claim 5, wherein:
the deep trench liner comprises a dielectric material;
the source/drain seed layer comprises silicon germanium (SiGe);
the source/drain comprises silicon (Si); and
the backside ILD comprises an oxide material.

7. The method of claim 1, further comprising:
forming a backside power rail on the backside of the semiconductor substrate such that a first surface contacts the backside contact;
forming a backside power distribution network on a second surface of the backside power rail opposite the first surface.

8. A semiconductor device comprising:
a first nanosheet stack on a front side of a semiconductor substrate and a second nanosheet stack on the front side of the semiconductor substrate separated from the first nanosheet stack by a source/drain region;
a deep nanosheet trench extending into the source/drain region between first and second nanosheet stacks;
a source/drain in the deep nanosheet trench and including a bottom end having a backside source/drain divot formed therein;
a deep trench liner interposed between the deep nanosheet trench and the source/drain, the deep trench liner having an opening exposing the bottom end of the source/drain; and
a backside contact on a backside of the semiconductor device, the backside contact physically contacting the exposed bottom end of the source/drain.

9. The semiconductor device of claim 8, wherein the deep trench liner contacts sidewalls of the source/drain, and wherein the backside contact fills the backside source/drain divot.

10. The semiconductor device of claim 9, wherein the backside contact does not extend past the deep trench liner.

11. The semiconductor device of claim 8, further comprising a first gate stack wrapping all around the first nanosheet stack and a second gate stack wrapping all around the second nanosheet stack.

12. The semiconductor device of claim 11, wherein a distance between the backside contact and one or both of the first and second gate stacks ranges from about 20 nm to about 90 nm.

13. The semiconductor device of claim 12, wherein the source/drain comprises a p-type semiconductor material and the backside contact comprises an electrically conductive material.

14. The semiconductor device of claim 13, further comprising:
a backside power rail contacting a first surface of the backside contact; and
a backside power distribution network on a second surface of the backside power rail opposite the first surface.

15. A semiconductor device comprising:
a first nanosheet stack on an upper surface of a front side of a semiconductor substrate, a second nanosheet stack on the upper surface, and a third nanosheet stack on the upper surface;
a first deep source/drain interposed between the first nanosheet stack the second nanosheet stack, and a second deep source/drain interposed between the second nanosheet stack the third nanosheet stack;
a backside contact on a backside of the semiconductor substrate and in physical contact with a first bottom end of the first deep source/drain; and
a source/drain seed layer in physical contact with a second bottom end of the second deep source/drain.

16. The semiconductor device of claim 15, wherein the second deep source/drain is completely separated from the backside contact.

17. The semiconductor device of claim 16, wherein the first deep source/drain excludes a source/drain seed layer.

18. The semiconductor device of claim 17, further comprising a gate stack wrapping all around the first nanosheet stack.

19. The semiconductor device of claim 18, further comprising:
a first deep trench liner on sidewalls of the first source/drain; and
a second deep trench liner on sidewalls of the second source/drain,
wherein a length of the second deep trench liner is greater than a length of the first deep trench liner.

20. The semiconductor device of claim 19, wherein the backside contact does not extend beyond the first deep trench liner.
